(19) United States
(12) Patent Application Publication
(10) Pub. No.: US 2025/0016972 A1
(43) Pub. Date: Jan. 9, 2025

(54) SEMICONDUCTOR DEVICE AND METHOD FOR MANUFACTURING THE SAME

(71) Applicant: UNITED MICROELECTRONICS CORP., Hsinchu (TW)

(72) Inventors: Kuan-Liang LIU, Hsinchu County (TW); Chiun-Min CHIOU, Hsinchu County (TW)

(21) Appl. No.: 18/231,806

(22) Filed: Aug. 9, 2023

(30) Foreign Application Priority Data
Jul. 6, 2023 (TW) 112125251

(51) Int. Cl. H10B 10/00

(52) U.S. Cl. CPC H10B 10/12

(57) ABSTRACT

A semiconductor device and methods for manufacturing the same are provided. The semiconductor device includes a substrate, a NFET structure on the substrate, and a PFET structure on the substrate. The NFET structure includes a first source region, a first drain region and a first gate structure between the first source region and the first drain region. The first gate structure includes a first high-k dielectric layer and a first gate layer on the first high-k dielectric layer. The PFET structure includes a second source region, a second drain region and a second gate structure between the second source region and the second drain region. The second gate structure includes a second high-k dielectric layer and a second gate layer on the second high-k dielectric layer. A thickness of the first high-k dielectric layer is larger than a thickness of the second high-k dielectric layer.

This application claims the benefit of Taiwan application Serial No. 112125251, filed on Jul. 6, 2023, the subject matter of which is incorporated herein by reference.

### BACKGROUND

### Technical Field

The disclosure relates to a semiconductor device and methods for manufacturing the same, and more particularly to a semiconductor device including a transistor and methods for manufacturing the same.

### Description of the Related Art

Semiconductor device including a n-type field-effect transistor structure and a p-type field-effect transistor structure has been widely used in various electronic products, such as notebooks, mobile devices, display devices, and game consoles. However, the performance of this type of semiconductor device is still insufficient to meet the market demand. There is still a need to provide an improved semiconductor device with improved electrical performance and a method for manufacturing the same.

### SUMMARY

The present disclosure relates to a semiconductor device and methods for manufacturing the same, through which the leakage current can be reduced or avoided.

According to an embodiment of the present disclosure, a semiconductor device is provided. The semiconductor device includes a substrate, a n-type field-effect transistor (NFET) structure on the substrate and a p-type field-effect transistor (PFET) structure on the substrate. The n-type field-effect transistor structure includes a first source region, a first drain region and a first gate structure between the first source region and the first drain region. The first gate structure includes a first high-k dielectric layer and a first gate layer on the first high-k dielectric layer. The p-type field-effect transistor structure includes a second source region, a second drain region and a second gate structure between the second source region and the second drain region. The second gate structure includes a second high-k dielectric layer and a second gate layer on the second high-k dielectric layer. A thickness of the first high-k dielectric layer is larger than a thickness of the second high-k dielectric layer.

According to another embodiment of the present disclosure, a method for manufacturing a semiconductor device is provided. The method includes: providing a substrate; forming a first source region, a first drain region, a second source region and a second drain region on the substrate; forming a first high-k material layer and a second high-k material layer on the substrate, wherein the first high-k material layer is between the first source region and the first drain region, and the second high-k material layer is between the second source region and the second drain region; removing the second high-k material layer; forming a third high-k material layer on the first high-k material layer; forming a fourth high-k material layer on the substrate, wherein the fourth high-k material layer is between the second source region and the second drain region; forming a first gate layer and a second gate layer on the third high-k material layer and the fourth high-k material layer respectively.

According to yet another embodiment of the present disclosure, a method for manufacturing a semiconductor device is provided. The method includes: providing a substrate; forming a first source region, a first drain region, a second source region and a second drain region on the substrate; forming a first high-k material layer and a second high-k material layer on the substrate, wherein the first high-k material layer is between the first source region and the first drain region, and the second high-k material layer is between the second source region and the second drain region; forming a third high-k material layer on the first high-k material layer; forming a first gate layer and a second gate layer on the third high-k material layer and the second high-k material layer respectively.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a schematic view of a semiconductor device according to an embodiment of the present disclosure.

FIG. 2 shows a schematic view of a semiconductor device according to an embodiment of the present disclosure.

FIG. 3 shows a schematic view of a memory cell according to an embodiment of the present disclosure.

FIGS. 4A to 4F illustrate a method for manufacturing a semiconductor device according to an embodiment of the present disclosure.

FIGS. 5A to 5C illustrate a method for manufacturing a semiconductor device according to another embodiment of the present disclosure.

### DETAILED DESCRIPTION

The illustrations may not be necessarily drawn to scale, and there may be other embodiments of the present disclosure which are not specifically illustrated. Thus, the specification and the drawings are to be regarded as an illustrative sense rather than a restrictive sense. Moreover, the descriptions disclosed in the embodiments of the disclosure such as detailed construction, manufacturing steps and material selections are for illustration only, not for limiting the scope of the disclosure. The steps and elements in details of the embodiments could be modified or changed according to the actual needs of the practical applications. It is contemplated that the elements and features of one embodiment can be beneficially incorporated in another embodiment without further recitation. The disclosure is not limited to the descriptions of the embodiments. The same reference numerals/letters refer to the same elements throughout the various figures.

Moreover, use of ordinal terms such as “first”, “second”, “third”, etc., in the specification and claims to modify an element or a step does not by itself imply any priority, precedence, or order of one claim element or step over another, but are used merely as labels to distinguish one claim element or step having a certain name from another element or step having the same name (but for use of the ordinal term) to distinguish the claim elements or steps.

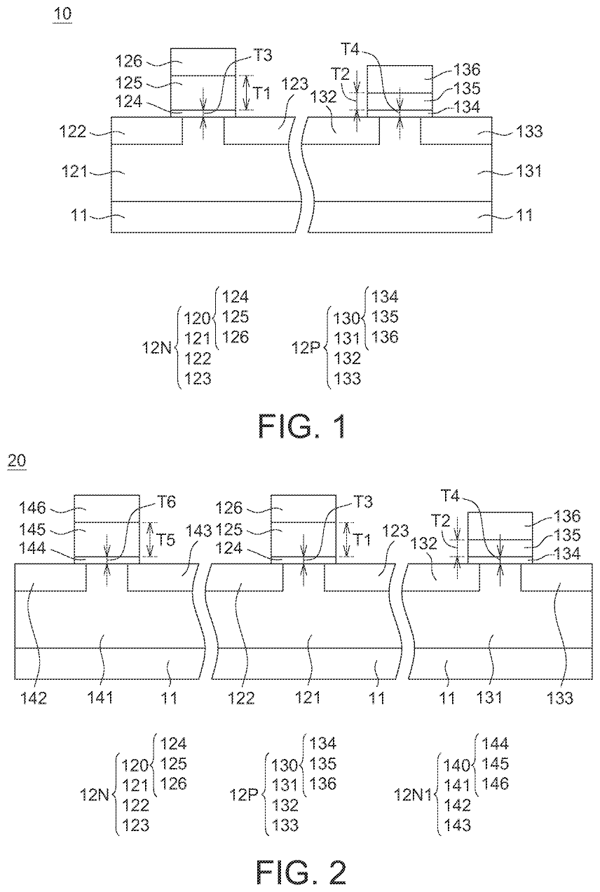

Please refer to FIG. 1, FIG. 1 shows a schematic view of a semiconductor device 10 according to an embodiment. The semiconductor device 10 includes a substrate 11, at least one n-type field-effect transistor (NFET) structure 12N on the substrate 11, and at least one p-type field-effect transistor (PFET) structure 12P on the substrate 11. The n-type field-effect transistor structure 12N includes a first well 121, a first source region 122, a first drain region 123 and a first gate structure 120. The first well 121 is on the substrate 11. The first source region 122 and the first drain region 123 are in the first well 121. The first gate structure 120 is on the first well 121. The first gate structure 120 is between the first source region 122 and the first drain region 123. The first gate structure 120 includes a first interfacial layer 124, a first high-k (high dielectric constant) dielectric layer 125 and a first gate layer 126. The first interfacial layer 124 is between the first high-k dielectric layer 125 and the first well 121. The first interfacial layer 124 may directly contact the first well 121, the first source region 122 and the first drain region 123. The first high-k dielectric layer 125 is between the first gate layer 126 and the first interfacial layer 124. The first high-k dielectric layer 125 may directly contact the first gate layer 126 and/or the first interfacial layer 124. The first gate layer 126 is on the first high-k dielectric layer 125. The substrate 11 can be a semiconductor substrate. In an embodiment, the substrate 11 includes silicon, germanium, silicon germanium, or other suitable semiconductor materials. The first well 121 may include a semiconductor material having p-type dopants. The first source region 122 and the first drain region 123 may include semiconductor materials having n-type dopants. The first interfacial layer 124 may include an oxide material, such as a thermal oxide material or a chemical oxide material. In an embodiment, the first interfacial layer 124 includes silicon dioxide (SiO₂). The first high-k dielectric layer 125 may include a high-k material. In an embodiment, the first high-k dielectric layer 125 includes at least one of Hafnium (IV) oxide (HfO₂), lanthanum (III) oxide (La₂O₃), and tantalum pentoxide (Ta₂O₅). The dielectric constant of the first high-k dielectric layer 125 may be between 10 and 35. The first gate layer 126 may include a conductive material. In an embodiment, the first gate layer 126 includes at least one of doped polycrystalline silicon, metal, metallic alloy, and metal silicide.

The p-type field-effect transistor structure 12P includes a second well 131, a second source region 132, a second drain region 133 and a second gate structure 130. The second well 131 is on the substrate 11. The second source region 132 and the second drain region 133 are in the second well 131. The second gate structure 130 is on the second well 131. The second gate structure 130 is between the second source region 132 and the second drain region 133. The second gate structure 130 includes a second interfacial layer 134, a second high-k dielectric layer 135 and a second gate layer 136. The second interfacial layer 134 is between the second high-k dielectric layer 135 and the second well 131. The second interfacial layer 134 may directly contact the second well 131, the second source region 132 and the second drain region 133. The second high-k dielectric layer 135 is between the second gate layer 136 and the second interfacial layer 134. The second high-k dielectric layer 135 may directly contact the second gate layer 136 and/or the second interfacial layer 134. The second gate layer 136 is on the second high-k dielectric layer 135. The second well 131 may include a semiconductor material having n-type dopants. The second source region 132 and the second drain region 133 may include semiconductor materials having p-type dopants. The second interfacial layer 134 may include an oxide material, such as a thermal oxide material or a chemical oxide material. In an embodiment, the second interfacial layer 134 includes silicon dioxide (SiO₂). The first interfacial layer 124 and the second interfacial layer 134 may include the same material or different materials. The second high-k dielectric layer 135 may include a high-k material. In an embodiment, the second high-k dielectric layer 135 includes at least one of Hafnium (IV) oxide (HfO₂), lanthanum (III) oxide (La₂O₃), and tantalum pentoxide (Ta₂O₅). The dielectric constant of the second high-k dielectric layer 135 may be between 10 and 35. The first high-k dielectric layer 125 and the second high-k dielectric layer 135 may include the same material or different materials. The second gate layer 136 may include a conductive material. In an embodiment, the second gate layer 136 includes at least one of doped polycrystalline silicon, metal, metallic alloy, and metal silicide. The first gate layer 126 and the second gate layer 136 may include the same material or different materials.

A thickness T1 of the first high-k dielectric layer 125 is larger than a thickness T2 of the second high-k dielectric layer 135. In an embodiment, the thickness T1 of the first high-k dielectric layer 125 is larger than 15 Å (Ångström). In an embodiment, the thickness T2 of the second high-k dielectric layer 135 is larger than 12 Å. A thickness T3 of the first interfacial layer 124 is approximately the same as a thickness T4 of the second interfacial layer 134. The thickness T3 of the first interfacial layer 124 may be smaller than the thickness T1 of the first high-k dielectric layer 125. The thickness T4 of the second interfacial layer 134 may be smaller than the thickness T2 of the second high-k dielectric layer 135. In an embodiment, the thickness T3 of the first interfacial layer 124 is smaller than 10 Å, and the thickness T4 of the second interfacial layer 134 is smaller than 10 Å.

Please refer to FIG. 2, FIG. 2 shows a schematic view of a semiconductor device 20 according to an embodiment. In FIG. 2, the same component numerals/letters as those in FIG. 1 represent the same elements, their detailed explanations are as described above and will not be repeated here. The semiconductor device 20 includes a substrate 11, at least one n-type field-effect transistor structure 12N1 on the substrate 11, at least one n-type field-effect transistor structure 12N on the substrate 11, and at least one p-type field-effect transistor structure 12P on the substrate 11. The n-type field-effect transistor structure 12N1 includes a third well 141, a third source region 142, a third drain region 143 and a third gate structure 140. The third well 141 is on the substrate 11. The third source region 142 and the third drain region 143 are in the third well 141. The third gate structure 140 is on the third well 141. The third gate structure 140 is between the third source region 142 and the third drain region 143. The third gate structure 140 includes a third interfacial layer 144, a third high-k dielectric layer 145 and a third gate layer 146. The third interfacial layer 144 is between the third high-k dielectric layer 145 and the third well 141. The third interfacial layer 144 may directly contact the third well 141, the third source region 142 and the third drain region 143. The third high-k dielectric layer 145 is between the third gate layer 146 and the third interfacial layer 144. The third high-k dielectric layer 145 may directly contact the third gate layer 146 and/or the third interfacial layer 144. The third gate layer 146 is on the third high-k dielectric layer 145. The third well 141 may include a semiconductor material having p-type dopants. The third source region 142 and the third drain region 143 may include semiconductor materials having n-type dopants. The third interfacial layer 144 may include an oxide material, such as a thermal oxide material or a chemical oxide material. In an embodiment, the third interfacial layer 144 includes silicon dioxide (SiO₂). The third high-k dielectric layer 145 may include a high-k material. In an embodiment, the third high-k dielectric layer 145 includes at least one of Hafnium (IV) oxide (HfO₂), lanthanum (III) oxide (La₂O₃), and tantalum pentoxide (Ta₂O₅). The dielectric constant of the third high-k dielectric layer 145 may be between 10 and 35. The third gate layer 146 may include a conductive material. In an embodiment, the third gate layer 146 includes at least one of doped polycrystalline silicon, metal, metallic alloy, and metal silicide. In this embodiment, a thickness T5 of the third high-k dielectric layer 145 is larger than the thickness T2 of the second high-k dielectric layer 135. The thickness T1 of the first high-k dielectric layer 125 is different from the thickness T5 of the third high-k dielectric layer 145. In an embodiment, the thickness T5 of the third high-k dielectric layer 145 can be larger than 15 Å. The thickness T3 of the first interfacial layer 124, the thickness T4 of the second interfacial layer 134 and the thickness T6 of the third interfacial layer 144 are approximately the same. The thickness T6 of the third interfacial layer 144 may be smaller than the thickness T5 of the third high-k dielectric layer 145. In an embodiment, the thickness T6 of the third interfacial layer 144 is smaller than 10 Å.

In an embodiment, the semiconductor device of the present disclosure can include a plurality of n-type field-effect transistor structures and a plurality of p-type field-effect transistor structures, thicknesses of the high-k dielectric layers of the n-type field-effect transistor structures can be the same or different from each other (such as the n-type field-effect transistor structure 12N1 and the n-type field-effect transistor structure 12N), and thicknesses of the high-k dielectric layers of the p-type field-effect transistor structures can be the same or different from each other. The thickness of at least one high-k dielectric layer of the n-type field-effect transistor structures is larger than the thickness of at least one high-k dielectric layer of the p-type field-effect transistor structures.

In an embodiment, the n-type field-effect transistor structure can be coupled to the p-type field-effect transistor structure to form a complementary Metal-Oxide-Semiconductor (CMOS).

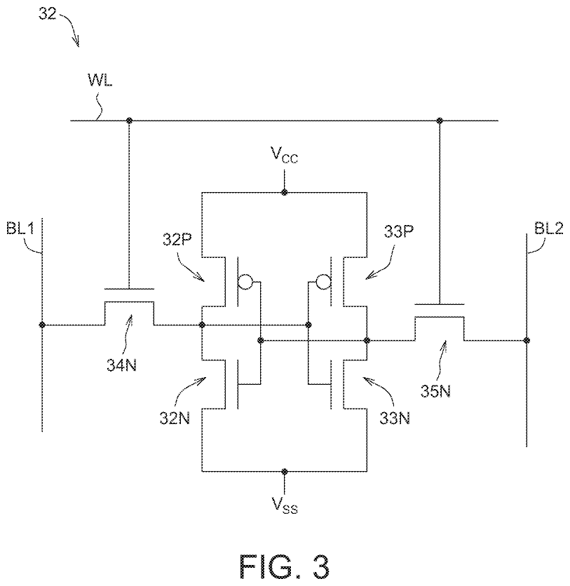

In an embodiment, the semiconductor device of the present disclosure can be applied to a semiconductor device including a memory device. For example, the semiconductor device includes a memory device, the memory device includes a substrate and a plurality of memory cells on the substrate, and each of the memory cells includes a plurality of n-type field-effect transistor structures and a plurality of p-type field-effect transistor structures. Take FIG. 3 as an example, the memory cell 32 includes n-type field-effect transistor structures 32N, 33N, 34N and 35N, and p-type field-effect transistor structures 32P and 33P. The memory cell 32 can be a memory cell of a static random-access memory. The p-type field-effect transistor structures 32P and 33P can function as pull-up transistors. The n-type field-effect transistor structures 32N and 33N can function as pull-down transistors. The n-type field-effect transistor structures 34N and 35N can function as pass gate transistors. The n-type field-effect transistor structure 32N and the p-type field-effect transistor structure 32P forms an inverter. The n-type field-effect transistor structure 33N and the p-type field-effect transistor structure 33P forms another inverter. The two inverters are coupled to each other to form a latch circuit for storing data. The source electrodes of the p-type field-effect transistor structures 32P and 33P are electrically connected to a power source V_{CC}. The source electrodes of the n-type field-effect transistor structures 32N and 33N are electrically connected to a power source V_{SS}. The drain electrode of the n-type field-effect transistor structure 34N is coupled to a bit line BL1. The gate electrode of the n-type field-effect transistor structure 34N is coupled to a word line WL. The drain electrode of the n-type field-effect transistor structure 35N is coupled to a bit line BL2. The gate electrode of the n-type field-effect transistor structure 34N is coupled to the word line WL. The structures of the n-type field-effect transistor structures 32N, 33N, 34N and 35N may independently be the structure of the n-type field-effect transistor structure 12N1 or the structure of the n-type field-effect transistor structure 12N shown in FIGS. 1 to 2. The structures of the p-type field-effect transistor structures 32P and 33P may be the structure of the p-type field-effect transistor structure 12P. Thicknesses of the high-k dielectric layers of the n-type field-effect transistor structures 32N, 33N, 34N and 35N can be the same or different from each other. Thicknesses of the high-k dielectric layers of the P-type field-effect transistor structures 32P and 33P can be the same or different from each other. The thickness of at least one high-k dielectric layer of the n-type field-effect transistor structures 32N, 33N, 34N and 35N is larger than the thickness of at least one high-k dielectric layer of the p-type field-effect transistor structures 32P and 33P. The memory cell 32 of FIG. 3 can be understood as a memory cell of a 6T (six-transistor) static random-access memory.

In other embodiments, the memory cell may include different numbers of n-type field-effect transistor structures and different numbers of p-type field-effect transistor structures. For example, the memory cell can be a memory cell of a 8T (eight-transistor) static random-access memory or a memory cell of a 10T (ten-transistor) static random-access memory.

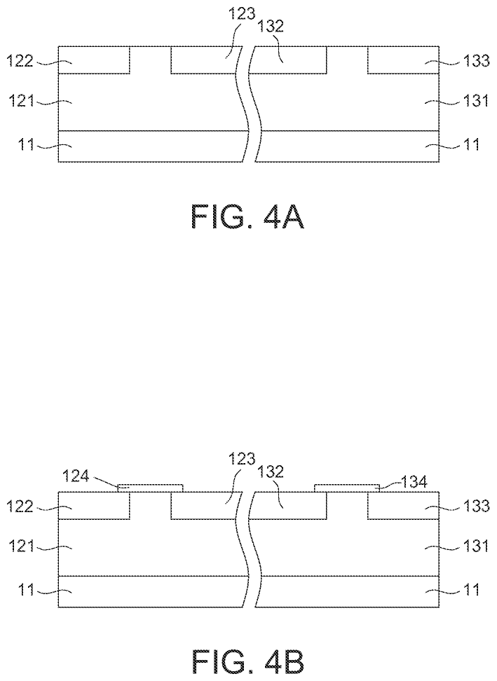

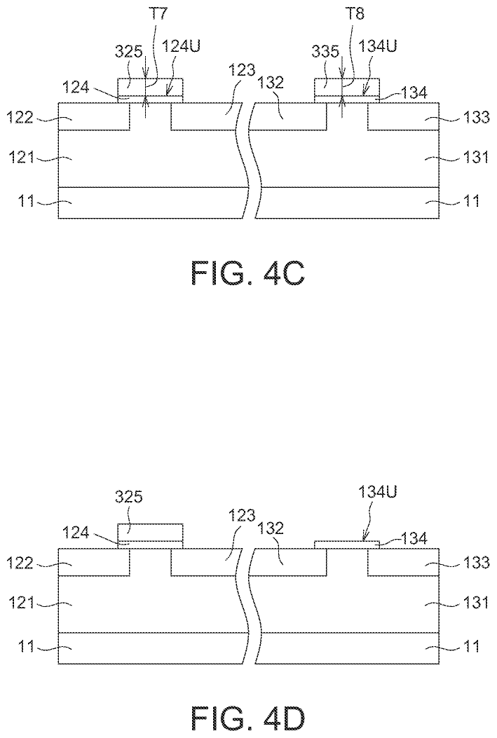

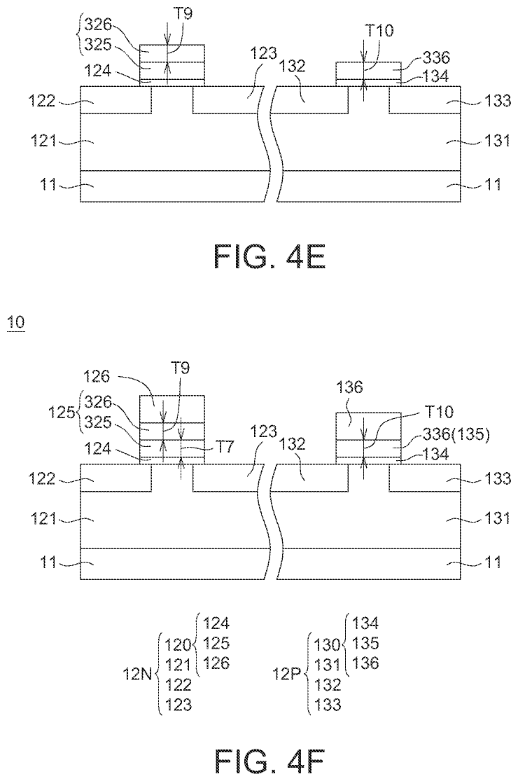

Please refer to FIGS. 4A to 4F, which illustrate a method for manufacturing a memory device according to an embodiment of the present disclosure.

Please refer to FIG. 4A, which illustrate a schematic view of a structure in a stage of the manufacturing method. A substrate 11 is provided. A first well 121, a first source region 122, a first drain region 123, a second well 131, a second source region 132 and a second drain region 133 are formed on the substrate 11. In an embodiment, an ion implantation process is performed to form the first well 121 and the second well 131, and another ion implantation process is performed to form the first source region 122, the first drain region 123, the second source region 132 and the second drain region 133. The first well 121 may include p-type dopants. The second well 131 may include n-type dopants. The first source region 122 and the first drain region 123 may include n-type dopants. The second source region 132 and the second drain region 133 may include p-type dopants.

Please refer to FIG. 4B, which illustrate a schematic view of a structure in a stage of the manufacturing method. A first interfacial layer 124 and a second interfacial layer 134 are formed on the substrate 11. The first interfacial layer 124 is between the first source region 122 and the first drain region 123. The second interfacial layer 134 is between the second source region 132 and the second drain region 133. In an embodiment, a deposition process is performed to form the first interfacial layer 124 on the first well 121 on the substrate 11, and the second interfacial layer 134 on the second well 131 on the substrate 11. The first interfacial layer 124 and the second interfacial layer 134 may be formed through the same deposition process, or through different deposition processes.

Please refer to FIG. 4C, which illustrate a schematic view of a structure in a stage of the manufacturing method. A first high-k material layer 325 and a second high-k material layer 335 are formed on the substrate 11. The first high-k material layer 325 is between the first source region 122 and the first drain region 123. The second high-k material layer 335 is between the second source region 132 and the second drain region 133. In an embodiment, a deposition process is performed to form the first high-k material layer 325 on an upper surface 124U of the first interfacial layer 124 on the substrate 11, and the second high-k material layer 335 on an upper surface 134U of the second interfacial layer 134 on the substrate 11. The first high-k material layer 325 may directly contact the first interfacial layer 124. The second high-k material layer 335 may directly contact the second interfacial layer 134. The first high-k material layer 325 and the second high-k material layer 335 may be formed through the same deposition process, or through different deposition processes. The first interfacial layer 124 and the first high-k material layer 325 includes different materials. The second interfacial layer 134 and the second high-k material layer 335 includes different materials. The first high-k material layer 325 and the second high-k material layer 335 may include the same material or different materials. A thickness T7 of the first high-k material layer 325 is approximately the same as a thickness T8 of the second high-k material layer 335. The first high-k material layer 325 and the second high-k material layer 335 include high-k materials. In an embodiment, the first high-k material layer 325 and the second high-k material layer 335 independently include at least one of Hafnium (IV) oxide (HfO₂), lanthanum (III) oxide (La₂O₃), and tantalum pentoxide (Ta₂O₅).

Please refer to FIG. 4D, which illustrate a schematic view of a structure in a stage of the manufacturing method. The second high-k material layer 335 is removed. In an embodiment, an etching process or a polishing process is performed to remove the second high-k material layer 335 and expose the upper surface 134U of the second interfacial layer 134. In this stage, a mask can be used to prevent the first high-k material layer 325 from being removed.

Please refer to FIG. 4E, which illustrate a schematic view of a structure in a stage of the manufacturing method. A third high-k material layer 326 is formed on the substrate 11. A fourth high-k material layer 336 is formed on the substrate 11. The fourth high-k material layer 336 is between the second source region 132 and the second drain region 133. In an embodiment, a deposition process is performed to form the third high-k material layer 326 on the first high-k material layer 325, and the fourth high-k material layer 336 on the second interfacial layer 134 on the substrate 11. The third high-k material layer 326 may directly contact the first high-k material layer 325. The fourth high-k material layer 336 may directly contact the second interfacial layer 134. The third high-k material layer 326 and the fourth high-k material layer 336 may be formed through the same deposition process, or through different deposition processes. In an embodiment, the first high-k material layer 325 and the third high-k material layer 326 include the same material, and there is no obvious interface between the first high-k material layer 325 and the third high-k material layer 326. In another embodiment, the first high-k material layer 325 and the third high-k material layer 326 include different materials, and there is an interface between the first high-k material layer 325 and the third high-k material layer 326. The third high-k material layer 326 and the fourth high-k material layer 336 include high-k materials. In an embodiment, the third high-k material layer 326 and the fourth high-k material layer 336 independently include at least one of Hafnium (IV) oxide (HfO₂), lanthanum (III) oxide (La₂O₃), and tantalum pentoxide (Ta₂O₅). A thickness T9 of the third high-k material layer 326 is approximately the same as a thickness T10 of the fourth high-k material layer 336.

Please refer to FIG. 4F, which illustrate a schematic view of a structure in a stage of the manufacturing method. A first gate layer 126 and a second gate layer 136 are formed. In an embodiment, a deposition process is performed to form the first gate layer 126 on the third high-k material layer 326, and the second gate layer 136 on the fourth high-k material layer 336. The first gate layer 126 and the second gate layer 136 may be formed through the same deposition process, or through different deposition processes. The first gate layer 126 and the second gate layer 136 may include the same material or different materials. A thickness of the first gate layer 126 is approximately the same as a thickness of the second gate layer 136.

In this embodiment, the first high-k material layer 325 and the third high-k material layer 326 can be defined as a first high-k dielectric layer (e.g. the first high-k dielectric layer 125 shown in FIG. 1). The fourth high-k material layer 326 can be defined as a second high-k dielectric layer (e.g. the second high-k dielectric layer 135 shown in FIG. 1). A sum of the thickness T7 of the first high-k material layer 325 and the thickness T9 of the third high-k material layer 326 is the thickness of the first high-k dielectric layer (e.g. the thickness T1 of the first high-k dielectric layer 125 shown in FIG. 1). The thickness T10 of the fourth high-k material layer 336 is the thickness of the second high-k dielectric layer (e.g. the thickness T2 of the second high-k dielectric layer 135 shown in FIG. 1). The sum of the thickness T7 of the first high-k material layer 325 and the thickness T9 of the third high-k material layer 326 can be larger than 15 Å. The thickness T10 of the fourth high-k material layer 336 can be larger than 12 Å.

In an embodiment, a semiconductor device 10 may be provided through the method schematically illustrated in FIGS. 4A to 4F.

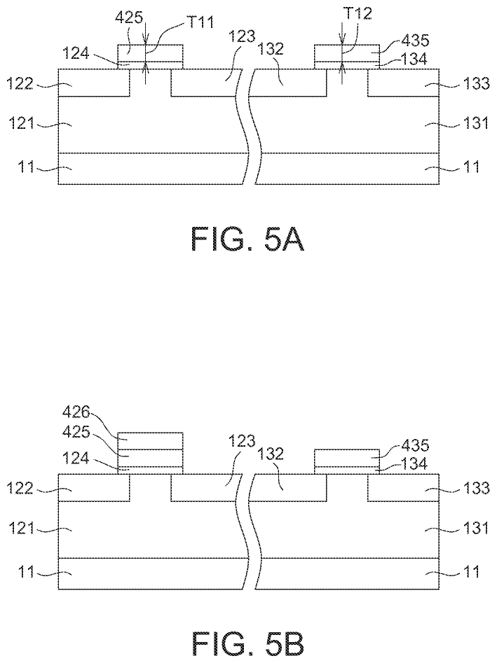

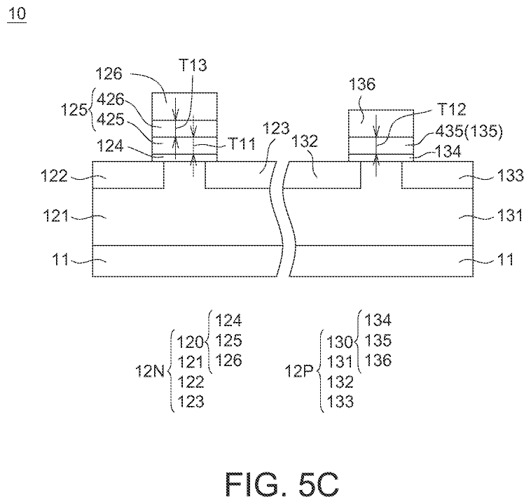

FIGS. 5A to 5C illustrate a method for manufacturing a memory device according to another embodiment of the present disclosure. In an embodiment, the steps illustrated with referring to FIGS. 5A to 5C may be performed after the steps illustrated with referring to FIGS. 4A and 4B.

Please refer to FIG. 5A, which illustrate a schematic view of a structure in a stage of the manufacturing method. A first high-k material layer 425 and a second high-k material layer 435 are formed on the substrate 11. The first high-k material layer 425 is between the first source region 122 and the first drain region 123. The second high-k material layer 435 is between the second source region 132 and the second drain region 133. In an embodiment, a deposition process is performed to form the first high-k material layer 425 on the first interfacial layer 124 on the substrate 11, and the second high-k material layer 435 on the second interfacial layer 134 on the substrate 11. The first high-k material layer 425 may directly contact the first interfacial layer 124. The second high-k material layer 435 may directly contact the second interfacial layer 134. The first high-k material layer 425 and the second high-k material layer 435 may be formed through the same deposition process, or through different deposition processes. The first interfacial layer 124 and the first high-k material layer 425 includes different materials. The second interfacial layer 134 and the second high-k material layer 435 includes different materials. The first high-k material layer 425 and the second high-k material layer 435 may include the same material or different materials. A thickness T11 of the first high-k material layer 425 is approximately the same as a thickness T12 of the second high-k material layer 435. The first high-k material layer 425 and the second high-k material layer 435 include high-k materials. In an embodiment, the first high-k material layer 425 and the second high-k material layer 435 independently include at least one of Hafnium (IV) oxide (HfO₂), lanthanum (III) oxide (La₂O₃), and tantalum pentoxide (Ta₂O₅).

Please refer to FIG. 5B, which illustrate a schematic view of a structure in a stage of the manufacturing method. A third high-k material layer 426 is formed. In an embodiment, a deposition process is performed to form the third high-k material layer 426 on the first high-k material layer 425 on the substrate 11. The third high-k material layer 426 may directly contact the first high-k material layer 425. In this stage, a mask can be used to avoid deposition of substances on the second high-k material layer 435. In an embodiment, the first high-k material layer 425 and the third high-k material layer 426 include the same material, and there is no obvious interface between the first high-k material layer 425 and the third high-k material layer 426. In another embodiment, the first high-k material layer 425 and the third high-k material layer 426, and there is an interface between the first high-k material layer 425 and the third high-k material layer 426. The third high-k material layer 426 includes a high-k material. In an embodiment, the third high-k material layer 426 includes at least one of Hafnium (IV) oxide (HfO₂), lanthanum (III) oxide (La₂O₃), and tantalum pentoxide (Ta₂O₅).

Please refer to FIG. 50, which illustrate a schematic view of a structure in a stage of the manufacturing method. A first gate layer 126 and a second gate layer 136 are formed. In an embodiment, a deposition process is performed to form the first gate layer 126 on the third high-k material layer 426, and the second gate layer 136 on the second high-k material layer 435.

The first gate layer 126 and the second gate layer 136 may be formed through the same deposition process, or through different deposition processes. The first gate layer 126 and the second gate layer 136 may include the same material or different materials. A thickness of the first gate layer 126 is approximately the same as a thickness of the second gate layer 136.

In this embodiment, the first high-k material layer 425 and the third high-k material layer 426 can be defined as a first high-k dielectric layer (e.g. the first high-k dielectric layer 125 shown in FIG. 1). The second high-k material layer 435 can be defined as a second high-k dielectric layer (e.g. the second high-k dielectric layer 135 shown in FIG. 1). A sum of the thickness T11 of the first high-k material layer 425 and the thickness T13 of the third high-k material layer 426 is the thickness of the first high-k dielectric layer (e.g. the thickness T1 of the first high-k dielectric layer 125 shown in FIG. 1). The thickness T12 of the second high-k material layer 435 is the thickness of the second high-k dielectric layer (e.g. the thickness T2 of the second high-k dielectric layer 135 shown in FIG. 1). The sum of the thickness T11 of the first high-k material layer 425 and the thickness T13 of the third high-k material layer 426 can be larger than 15 Å. The thickness T12 of the second high-k material layer 435 can be larger than 12 Å.

In an embodiment, a semiconductor device 10 may be provided through the method schematically illustrated in FIGS. 5A to 5C.

In other embodiments, a semiconductor device including a plurality of n-type field-effect transistor structures and a plurality of p-type field-effect transistor structures may be provided by performing steps similar to those schematically illustrated in FIGS. 4A to 4F or FIGS. 5A to 5C.

In the semiconductor device according to the present disclosure, the thickness of the high-k dielectric layer of the n-type field-effect transistor structure is larger than the thickness of the high-k dielectric layer of the p-type field-effect transistor structure, such that the leakage current can be reduced or avoided, the minimum operating voltage and power consumption can be reduced, and the electrical performance of the semiconductor device or memory device can be improved. Moreover, the thickness of the interfacial layer of the semiconductor device is smaller than 10 Å, which can effectively improve the electrical performance of the semiconductor device or memory device. In addition, with a low power consumption, the semiconductor device according to the present disclosure is suitable for various low-power devices, such as display driver IC (DDIC) and low voltage CMOS.

The present disclosure is not limited to the above embodiments and can be adjusted or varied properly according to actual demands. For example, the semiconductor device may comprise other layers or have other arrangements. Therefore, the specification and the structures shown in the drawings are used to describe the concepts of the embodiments, and the scope of the invention is not limited thereto. Moreover, it could be understood that the elements in the embodiments are not limited to the shape and the configuration shown in the drawings, and can be adjusted according to the demand and/or process steps of actual applications without deviating from the spirit of the invention.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a n-type field-effect transistor (NFET) structure on the substrate and comprising a first source region, a first drain region and a first gate structure between the first source region and the first drain region, wherein the first gate structure comprises a first high-k dielectric layer and a first gate layer on the first high-k dielectric layer; and
a p-type field-effect transistor (PFET) structure on the substrate and comprising a second source region, a second drain region and a second gate structure between the second source region and the second drain region, wherein the second gate structure comprises a second high-k dielectric layer and a second gate layer on the second high-k dielectric layer,
wherein a thickness of the first high-k dielectric layer is larger than a thickness of the second high-k dielectric layer.

2. The semiconductor device according to claim 1, wherein the first gate structure of the n-type field-effect transistor structure comprises a first interfacial layer, and the first high-k dielectric layer is between the first gate layer and the first interfacial layer,
wherein the second gate structure of the p-type field-effect transistor structure comprises a second interfacial layer, and the second high-k dielectric layer is between the second gate layer and the second interfacial layer.

3. The semiconductor device according to claim 2, wherein a thickness of the first interfacial layer is approximately the same as a thickness of the second interfacial layer.

4. The semiconductor device according to claim 2, wherein a thickness of the first interfacial layer is smaller than 10 Å (Ångström).

5. The semiconductor device according to claim 1, wherein a dielectric constant of the first high-k dielectric layer is between 10 and 35.

6. The semiconductor device according to claim 1, wherein the thickness of the first high-k dielectric layer is larger than 15 Å.

7. The semiconductor device according to claim 1, wherein the thickness of the second high-k dielectric layer is larger than 12 Å.

8. The semiconductor device according to claim 1, further comprising a memory cell, wherein the memory cell comprises a plurality of the n-type field-effect transistor structures and a plurality of the p-type field-effect transistor structures.

9. The semiconductor device according to claim 1, further comprising:
another n-type field-effect transistor (NFET) structure on the substrate and comprising a third source region, a third drain region and a third gate structure between the third source region and the third drain region, wherein the third gate structure comprises a third high-k dielectric layer and a third gate layer on the third high-k dielectric layer,
wherein a thickness of the third high-k dielectric layer is larger than the thickness of the second high-k dielectric layer, and the thickness of the first high-k dielectric layer is different from the thickness of the third high-k dielectric layer.

10. A method for manufacturing a semiconductor device, comprising:
providing a substrate;
forming a first source region, a first drain region, a second source region and a second drain region on the substrate;
forming a first high-k material layer and a second high-k material layer on the substrate, wherein the first high-k material layer is between the first source region and the first drain region, and the second high-k material layer is between the second source region and the second drain region;
removing the second high-k material layer;
forming a third high-k material layer on the first high-k material layer;
forming a fourth high-k material layer on the substrate, wherein the fourth high-k material layer is between the second source region and the second drain region; and
forming a first gate layer and a second gate layer on the third high-k material layer and the fourth high-k material layer respectively.

11. The method according to claim 10, wherein a thickness of the first high-k material layer is approximately the same as a thickness of the second high-k material layer, and a thickness of the third high-k material layer is approximately the same as a thickness of the fourth high-k material layer.

12. The method according to claim 10, further comprising:
forming a first interfacial layer on the substrate, wherein the first interfacial layer is between the first source region and the first drain region;
forming a second interfacial layer on the substrate, wherein the second interfacial layer is between the second source region and the second drain region,
wherein the first interfacial layer and the first high-k material layer comprise different materials.

13. The method according to claim 12, wherein a thickness of the first interfacial layer is smaller than 10 Å.

14. The method according to claim 10, wherein the first high-k material layer and the third high-k material layer comprise the same material.

15. The method according to claim 10, further comprising:
performing an ion implantation process to form the first source region, the first drain region, the second source region and the second drain region,
wherein the first source region and the first drain region comprise n-type dopants, and the second source region and the second drain region comprise p-type dopants.

16. A method for manufacturing a semiconductor device, comprising:
providing a substrate;
forming a first source region, a first drain region, a second source region and a second drain region on the substrate;
forming a first high-k material layer and a second high-k material layer on the substrate, wherein the first high-k material layer is between the first source region and the first drain region, and the second high-k material layer is between the second source region and the second drain region;
forming a third high-k material layer on the first high-k material layer; and
forming a first gate layer and a second gate layer on the third high-k material layer and the second high-k material layer respectively.

17. The method according to claim 16, further comprising:
forming a first interfacial layer on the substrate, wherein the first interfacial layer is between the first source region and the first drain region;
forming a second interfacial layer on the substrate, wherein the second interfacial layer is between the second source region and the second drain region,
wherein the first interfacial layer and the first high-k material layer comprise different materials.

18. The method according to claim 17, wherein a thickness of the first interfacial layer is smaller than 10 Å.

19. The method according to claim 16, wherein a thickness of the second high-k material layer is larger than 12 Å.

20. The method according to claim 10, wherein a sum of a thickness of the first high-k material layer and a thickness of the third high-k material layer is larger than 15 Å.
